(19) United States
(12) Patent Application Publication
(10) Pub. No.: US 2021/0211061 A1
(43) Pub. Date: Jul. 8, 2021

(54) Converter

(71) Applicant: Siemens Aktiengesellschaft, Muenchen (DE)

(72) Inventor: Martin Schulz, München (DE)

(73) Assignee: Siemens Aktiengesellschaft, Muenchen (DE)

(21) Appl. No.: 15/999,479

(22) PCT Filed: Jan. 25, 2017
(86) PCT No.: PCT/EP2017/051458

§ 371 Date: Aug. 17, 2018

(30) Foreign Application Priority Data
Feb. 17, 2016 (EP) 16156055.2

(51) Int. Cl. H02M 7/00; H02M 7/483; H05K 7/20

(52) U.S. Cl. CPC H02M 7/003; H02M 2007/4835; H05K 7/209; H02M 7/483

(57) ABSTRACT

Various embodiments may include a converter for converting an input voltage applied between two input terminals into an alternating voltage with a predetermined amplitude and frequency for driving a single-phase or multi-phase load, comprising at least two submodules of an inverter arm connected in series with one another. Each submodule may include: a circuit carrier; two switching elements connected on the circuit carrier; a first submodule terminal; and a second submodule terminal. First main terminals of the two switching elements are thermally connected to a cooling body. The second submodule terminal of a first submodule is connected to the first submodule terminal of a second. The connection of the second submodule terminal of the first submodule to the first submodule terminal of the second submodule comprises a conductive layer applied to the cooling surface.

### CROSS-REFERENCE TO RELATED APPLICATIONS

This application is a U.S. National Stage Application of International Application No. PCT/EP2017/051458 filed Jan. 25, 2017, which designates the United States of America, and claims priority to EP Application No. 16156055.2 filed Feb. 17, 2016, the contents of which are hereby incorporated by reference in their entirety.

### TECHNICAL FIELD

The present disclosure relates to electrical circuits. Various embodiments may include a converter for converting an input voltage applied between two input terminals into an alternating voltage with a predetermined amplitude and frequency for driving a single-phase or multi-phase load, comprising at least two submodules of an inverter arm connected in series with one another.

### BACKGROUND

Modern modular converter topologies with a multi-level characteristic consist of identically constructed functional units that are denoted as submodules and are configured either as half-bridge or full-bridge submodules. These are connected in series to provide an inverter phase. The connection of a large number of half-bridge submodules in series occupies a large amount of structural space. This results in a high cost for the converter.

In the low voltage domain, it is usual to construct modular topologies from, generally circuit board-based, submodules with discrete power semiconductor switching elements. Through the use of circuit boards, further problems arise due to the restricted current-carrying capacity of the circuit boards and, as compared with power modules in which the power semiconductor switching elements are mounted directly on a carrier (by Direct Copper Bonding (DCB)), poorer cooling conditions. Significant current heating losses which must be dissipated arise in the connecting cables and the contact sites between connecting cables and circuit boards.

The electric connection between the discrete power semiconductor switching elements and the screw or clamping contacts of the cable is realized by means of copper tracks on the circuit carriers. to guarantee the necessary current carrying capacity, expensive high current circuit carriers are used. These are known as thick copper boards or circuit boards with inlaid copper profiles.

The heat dissipation in a circuit-board-based converter takes place directly at a main terminal (typically the drain or collector terminal of the power semiconductor switching element). The power semiconductor switching element is pressed directly with its large-area terminal contact onto a cooling body. To prevent an electrical connection between the terminal contact and the cooling body, an insulator is arranged between these two surfaces. The current heating losses in the connecting cables and in the contact sites can be minimized and conducted away by using larger cable cross-sections and larger contacts. However, this in turn leads to the construction and connection technology becoming very large and heavy. The circuit board-based converter, however, is often preferred over DCB-based converters, since such a converter has better electrical properties.

### SUMMARY

The teachings of the present disclosure may be embodied in a converter that is improved structurally and/or functionally. For example, some embodiments may include a converter for converting an input voltage (U₁) applied between two input terminals (101, 102) into an alternating voltage with a predetermined amplitude and frequency for driving a single-phase or multi-phase load, comprising at least two submodules (SM; SM1, . . . , SM8) of an inverter arm connected in series with one another, each submodule (SM; SM1, . . . , SM8) comprising the following: a circuit carrier (11); at least two controllable switching elements (S₁, S₂) which are electrically connected to one another on the circuit carrier (11); a first submodule terminal (X₁); a second submodule terminal (X₂); in which first main terminals (D) of the controllable switching elements (S₁, S₂) of the at least two submodules (SM; SM1, . . . , SM8) are thermally a really connected to a cooling area of a cooling body (12); the second submodule terminal (X₂) of a first of the at least two submodules (SM; SM1, . . . , SM8) is connected to the first submodule terminal (X₁) of a second of the at least two submodules (SM; SM1, . . . , SM8); characterized in that the connection of the second submodule terminal (X₂) of the first submodule (SM; SM2, . . . , SM8) to the first submodule terminal (X₁) of the second submodule (SM; SM1, . . . , SM7) is realized by means of a conductive layer (16) applied to the cooling surface.

In some embodiments, the first main terminals (D) of the switching elements (S₁, S₂) are areal contacts which are applied with their full area onto the conductive layer (16).

In some embodiments, the first main terminals (D) of the switching elements (S₁, S₂) are connected frictionally and/or integrally bonded to the conductive layer (16).

In some embodiments, the conductive layer (16) is a metal rail which is connected to the cooling body (12) via an insulating layer (13).

In some embodiments, the electrical connection between the second main terminal (S) of the first switching element (S₁) and the first main terminal (D) of the second switching element (S₂) of a respective half-bridge submodule (SM; SM1, . . . , SM8) is realized via one or more conductor tracks of the circuit carrier (11) of the half-bridge submodule.

In some embodiments, for each phase, two inverter arms are connected in series between the two input terminals, a node point between the two inverter arms being coupled to an output terminal of an inverter phase.

In some embodiments, the converter comprises at least two submodules (SM; SM1, . . . , SM8) per inverter arm and phase.

In some embodiments, a respective submodule (SM; SM1, . . . , SM8) comprises a half-bridge with two controllable switching elements (S₁, S₂) connected in series; the first submodule terminal (X₁) is electrically connected to a first main terminal (D) of a first of the at least two switching elements (S₁, S₂); the second submodule terminal (X₂) is electrically connected to a node point of a second main terminal (S) of the first switching element (S₁) and a first main terminal (D) of a second of the at least two switching elements (S₂).

In some embodiments, the submodule (SM; SM1, . . . , SM8) comprises a full-bridge with two half-bridges connected in parallel, wherein in a first of the half-bridges a first and a second switching element are connected in series and in a second of the half-bridges a third and a fourth switching element are connected in series; the first submodule terminal (X₁) is electrically connected to a node point of a second main terminal (S) of the first switching element and to a first main terminal (D) of the second switching element; the second submodule terminal (X₂) is electrically connected to a node point of a second main terminal (S) of the third switching element and to a first main terminal (D) of the fourth switching element; the first main terminals (D) of the first and third switching element are electrically connected to one another via a further conductive layer on the cooling surface. In some embodiments, the further conductive layer is arranged between the conductive layers of the first and second submodule terminals (X₁, X₂) on the cooling body.

### BRIEF DESCRIPTION OF THE DRAWINGS

The teachings will now be described in greater detail making reference to an exemplary embodiment in the drawings, in which:

FIG. 1 shows the series connection of a number of submodules to provide an inverter phase between an input connection and an output connection, in accordance with teachings of the present disclosure;

FIG. 2 is an electric equivalent circuit diagram of a half-bridge submodule, in accordance with teachings of the present disclosure;

FIG. 3 is a schematic representation of two half-bridge submodules arranged on a cooling body in a conventional design variant, in accordance with teachings of the present disclosure; and

FIG. 4 is a schematic representation of a plurality of half-bridge submodules on a cooling body, in accordance with teachings of the present disclosure.

### DETAILED DESCRIPTION

Some embodiments include a converter for converting an input voltage applied between two input terminals into an alternating voltage with a predetermined amplitude and frequency for driving a single-phase or multi-phase load, comprising at least two submodules of an inverter arm connected in series with one another, each submodule comprising the following: a circuit carrier; at least two controllable switching elements which are electrically connected to one another on the circuit carrier; a first submodule terminal; a second submodule terminal. First main terminals of the controllable switching elements of the at least two submodules are thermally connected to a cooling area of a cooling body. The second submodule terminal of a first of the at least two submodules is connected to a first submodule terminal of a second of the at least two half-bridge submodules.

In some embodiments, the connection of the second submodule terminal of the first submodule to the first submodule terminal of the second submodule includes a conductive layer applied to the cooling surface. In some embodiments, the converter includes submodules constructed based on circuit boards. This allows the provision of good electrical properties of the submodules and, overall, of the converter. At the same time, by the connection of the submodule terminals via a conductive layer applied to the cooling surface, good dissipation of the heat generated during operation in the semiconductor switching elements is enabled. In particular, this construction enables the electrical contacts to be cooled directly.

By means of an exclusive contacting of the submodules by means of the first main terminals of the two switching elements, the serial connection of the submodules can be very compactly constructed. In particular the fastening effort is minimized. Furthermore, a direct cooling of the electrical contacts and of the conductive layer is realized. Further, a reduced current flow arises on the circuit carrier of the submodules as compared with a conventional submodule, since the current is drawn directly via the first main terminals of the switching elements. In some embodiments, there is a lower thermal loading on the circuit carrier.

In some embodiments, the first main terminals of the switching elements are areal contacts which are applied with their full area onto the conductive layer. By this means, a large current-carrying capacity may be provided. In some embodiments, by the first main terminals, the thermal transfer of the heat generated in the switching elements can take place in the direction of the conductive layer and the cooling body. In addition, the production capability is simplified since the first main terminals can be easily connected to the cooling body via the conductive layer. In some embodiments, commercially available discrete power semiconductor switching elements can be used as switching elements of the submodules.

In some embodiments, the first main terminals of the switching elements are frictionally connected and/or integrally bonded to the conductive layer. By this means, a good current-carrying capacity between the first main terminals of switching elements of adjacent submodules via the conductive layer is ensured. At the same time, a good heat transfer to the cooling body is ensured.

In some embodiments, the conductive layer is a metal rail which is connected to the cooling body via the insulating layer.

In some embodiments, the electrical connection, i.e. the node point between the second main terminal of the first switching element and the first main terminal of the second switching element of a respective submodule is realized via one or more conductor tracks of the circuit carrier of the submodule. For this purpose, the circuit carrier can comprise so-called thick conductor tracks (i.e. conductor tracks with thicknesses of greater than 400 μm). In some embodiments, for each phase, two inverter arms are connected in series between the two input terminals, a node point between the two inverter arms being coupled to an output terminal of an inverter phase. In particular, the converter comprises at least two submodules per inverter arm and phase.

In some embodiments, a respective submodule comprises a half-bridge with two controllable and switching elements connected in series. The first submodule terminal is electrically connected to a first main terminal of a first of the at least two switching elements (high-side switching element). The second submodule terminal is electrically connected to a node point of a second main terminal of the first switching element and a first main terminal of a second of the at least two switching elements (low-side switching element).

In some embodiments, the submodule comprises a full-bridge with two half-bridges connected in parallel, wherein in a first of the half-bridges a first and a second switching element are connected in series and in a second of the half-bridges, a third and a fourth switching element are connected in series. The first submodule terminal is electrically connected to a node point of a second main terminal of the first switching element and to a first main terminal of the second switching element. The second submodule terminal is electrically connected to a node point of a second main terminal of the third switching element and to a first main terminal of the fourth switching element. The first main terminals of the first and third switching element are electrically connected to one another via a further conductive layer on the cooling surface. In some embodiments, the further conductive layer is arranged between the conductive layers of the first and second submodule terminals on the cooling body.

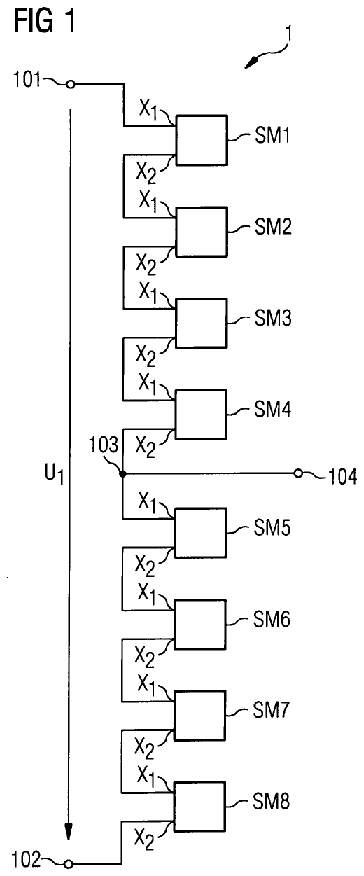

FIG. 1 shows such an inverter phase of a converter in a so-called multilevel topology. Here, by way of example, eight identically constructed submodules SM1, . . . , SM8 are connected together between an input terminal 101 and an input terminal 102. A node point 103 between the half-bridge submodules SM4 and SM5 is connected to an output terminal 104 of the inverter phase. The submodules SM1, . . . , SM4 connected between the input terminal 101 and the node point 103 are assigned to an upper inverter arm. The submodules SM1, . . . , SM8 connected in series between the node point 103 and the input terminal 102 are assigned to a lower inverter arm. A direct current voltage U₁ is applied between the input terminals 101 and 102. The input terminals 101, 102 are terminals of a DC link (not shown). By means of a control circuit (also not shown) which controls the switching elements contained in the respective submodules SM1, . . . , SM8 and in a suitable manner switches them conducting and blocking, an alternating voltage can be drawn off at the output terminal 104.

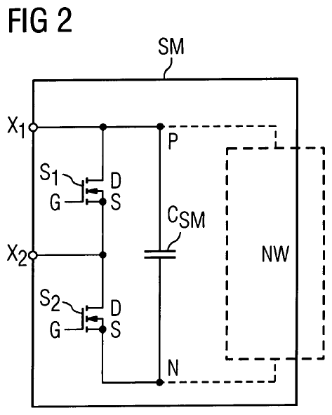

FIG. 2 shows an electrical equivalent circuit diagram of the identically constructed submodules SM1, SM8 in the form of a half-bridge submodule. Thus, each of the half-bridge submodules SM comprises two series-connected switching elements S₁, S₂. The switching elements S₁, S₂ are, for example, MOSFETs or other controllable semiconductor switching elements. The first main terminal of the switching element S₁ designated the drain D is connected to a first submodule terminal X₁. The second main terminal of the switching element S₁ designated the source S is connected to the drain terminal D of the second switching element S₂. The node point between the source terminal S of the switching element S₁ and the drain terminal of the switching element S₂ forms a second submodule terminal X₂. The source terminal of the second switching element S₂ is connected to the drain terminal of the first switching element S₁ via a capacitor C_{SM}. At the node points designated by the reference characters P and N, an optional output network NW can be connected in parallel with the capacitor C_{SM}.

In order to provide an inverter phase with a multilevel characteristic, as shown in FIG. 1, the submodule terminals X₁, X₂ of the respective half-bridge submodules are connected in series with one another. Thus, as is readily apparent from FIG. 1, the first submodule terminal X₁ of the submodule SM1 is connected to the input terminal 101. The second submodule terminal X₂ of the submodule SM1 is connected to the first submodule terminal X₁ of the submodule SM2. The second submodule terminal X₂ of the submodule SM2 is connected in turn to the first submodule terminal of the submodule SM3, etc. Finally, the second submodule terminal X₂ of the submodule SM8 is connected to the input terminal 102. As is also readily apparent from FIG. 1, the output terminal 104 of the inverter phase of the converter 1 is connected via the node point 103 both to the second submodule terminal X₂ of the submodule SM4 as well as to the first submodule terminal X₁ of the submodule SM5.

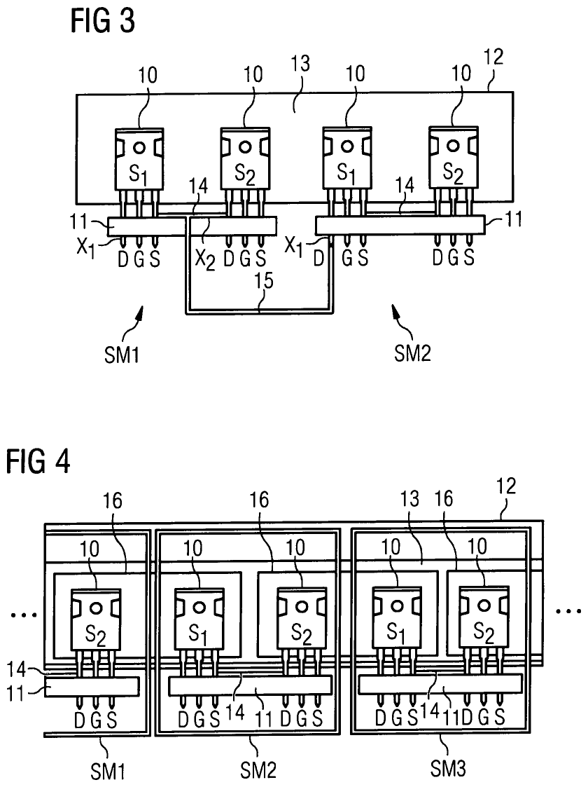

This connection requires a large amount of structural space in the converter 1. FIG. 3 shows a possible variant of the construction for two submodules SM1, SM2 based on circuit boards and arranged adjacently on one cooling body 12. In this variant, each submodule SM1, SM2 is constructed using discrete power semiconductor switching elements and a circuit carrier. By this means, as compared with the direct copper bonding (DCB) known from the prior art, better electrical properties are achieved.

The submodules SM1, SM2 (this naturally also applies in a similar way for the further submodules SM3, . . . , SM8 not shown in FIG. 3) each comprise a circuit carrier 11. Mounted on the circuit carrier 11 in each case are two power semiconductor switching elements 10. Each of the power semiconductor switching elements comprises three contact pins which are inserted through corresponding openings or bores (not shown in FIG. 3) of the circuit carrier 11 and are soldered. The three contact pins represent the drain terminal D (first main terminal), the source terminal S (second main terminal) and the gate terminal G (control terminal). An electrical connection between the source terminal of the power semiconductor switching element 10 designated S₁ and the drain terminal of the power semiconductor switching element 10 designated S₂ takes place via a conductor track 14. Due to the large current flowing, the conductor track 14 can be configured as a thick copper conductor track. The electrical connection between the source terminal S of S₁ and the drain terminal D of S₂ forms the second submodule terminal X₂ described in relation to FIG. 2. The first submodule terminal X₁ is the drain terminal D of the power semiconductor switching element 10 designated S₁.

The heat dissipation of the power semiconductor switching elements takes place directly at their drain terminals D by direct pressing of the drain terminals D formed on the rear side of the discrete power semiconductor switching elements 10 onto the aforementioned cooling body 12. In order to prevent a short-circuit of the drain terminals D via the cooling body 12, an insulating layer 13 with good thermal conduction is applied to the side of the cooling body 12 facing the viewer. In order to ensure an intimate contact between the rear-side contacts (drain terminals) of the power semiconductor switching elements 10 and the cooling body 12, the power semiconductor switching elements could be, for example, screwed onto the cooling body 12.

For the production of the electrical connection between the second submodule terminal X₂ of the submodule SM1 and the first submodule terminal X₁ of the submodule SM2, in the arrangement of FIG. 3, a cable 15 is used. This is electrically screwed, for example, between corresponding contact surfaces of the circuit carriers 11 in the manner shown in FIG. 3. Due to the current heating losses occurring at the contact sites between the cable 15 and the corresponding circuit carriers 11 of the half-bridge submodules SM1, SM2, large cable cross-sections and large contacts are used. However, this in turn leads to the construction and connection technology becoming very large and heavy.

FIG. 4 shows an example embodiment. In FIG. 4, the switching module SM1 is partially shown, together with the switching modules SM2 and SM3 connected to it in series. The electrical connection identified in FIG. 3 with the reference character 15 is replaced in each case by a conductive layer 16 which is arranged on the cooling body 12 between the discrete power semiconductor switching elements 10 and the insulating layer 13. Herein, the drain terminal of the second switching element S₂ of a half-bridge submodule (e.g. SM1) and the drain terminal of the first switching element S₁ of the adjacent half-bridge submodule (SM2) are applied to the conductive layer 16 and are electrically conductively connected thereto. In a similar way, the drain terminal of the second switching element S₂ of the half-bridge submodule SM2 and the drain terminal D of the first switching element S₁ of the adjacent half-bridge submodule (in this case, SM3) are applied to another conductive layer. Applied respectively to a conductive layer 16, therefore, in pairs are the drain terminals of the switching elements of adjacent half-bridge submodules.

By means of the exclusive contacting of the drain terminals D of the half-bridge submodules SM of the discrete power semiconductor switching elements, the series connection of the half-bridge submodules can be configured very compactly. The result is, in particular, a compact series connection with minimal fastening effort. A direct cooling of the electrical contacts and of the electrical layers is possible. The electrical layers are realized, for example, in the form of metal rails.

The node point or output terminal can be realized with the aid of the conductive layer. Thus, the conductive layer can comprise, for example, a tab (not shown) facing away from the circuit carriers, so that in the areal region of the tab, a screw fixing or plug-in connection to the output terminal can take place. There results a reduced current flow via the respective circuit carrier of the half-bridge submodules since a majority of the current is drawn directly at the drain terminals of the power semiconductor switching elements. By this means, there is a lower thermal loading of the respective circuit carriers.

In some embodiments, all contacting sites (i.e. the drain terminals of the power semiconductor switching elements) are simultaneously those sites at which the heat of the power semiconductor switching elements is dissipated. By this means, a reversal of the previous separation between electrical and thermal paths takes place. Rather, these now match one another. The heat dissipation of the semiconductor switching elements to the cooling body 12 is influenced only minimally by the electrically conductive layer 16, since it can be provided with a very high thermal conductivity. In some embodiments, the conductive layers 16 consist of copper or aluminum or alloys thereof.

In the present exemplary embodiment, the depiction in FIGS. 2 to 4 has been described on the basis of half-bridge submodules of an inverter phase. The teachings herein can also be applied without difficulty to full-bridge submodules. A full-bridge submodule comprises four switching elements in two parallel paths, wherein two of the switching elements are connected in series with each other per path. In such full-bridge submodules, the drain terminals of the two high-side switching elements are connected to a common electrically conductive layer. The low-side switching elements, however, are connected to switching elements of two respectively adjacent full-bridge submodules via a conductive layer.

What is claimed is:

1. A converter for converting an input voltage between two input terminals into an alternating voltage with a predetermined amplitude and frequency for driving a single-phase or multi-phase load, the converter comprising:
two submodules of an inverter arm connected in series with one another, each submodule comprising:
a circuit carrier;
two controllable switching elements electrically connected to one another on the circuit carrier;
a first submodule terminal; and
a second submodule terminal;
wherein first main terminals of the two controllable switching elements of the two submodules are thermally connected to a cooling area of a cooling body;
the second submodule terminal of a first of the two submodules is connected to the first submodule terminal of a second of the two submodules
the connection of the second submodule terminal of the first submodule to the first submodule terminal of the second submodule comprises a conductive layer applied to the cooling surface.

2. The converter as claimed in claim 1, wherein the first main terminals of the switching elements comprise areal contacts applied with their full area onto the conductive layer.

3. The converter as claimed in claim 1, wherein the first main terminals of the switching elements are connected frictionally and/or integrally bonded to the conductive layer.

4. The converter as claimed in claim 1, wherein the conductive layer comprises a metal rail connected to the cooling body with an insulating layer.

5. The converter as claimed in claim 1, wherein the electrical connection between the second main terminal of the first switching element and the first main terminal of the second switching element of a respective half-bridge submodule comprises one or more conductor tracks of the circuit carrier of the half-bridge submodule.

6. The converter as claimed in claim 1, wherein, for each phase, two inverter arms are connected in series between the two input terminals, and a node point is coupled between the two inverter arms to an output terminal of an inverter phase.

7. The converter as claimed in claim 6, wherein the converter comprises two submodules per inverter arm and phase.

8. The converter as claimed in claim 1, wherein:
a respective submodule comprises a half-bridge with two controllable switching elements connected in series;
the first submodule terminal is electrically connected to a first main terminal of a first of the two switching elements;
the second submodule terminal is electrically connected to a node point of a second main terminal of the first switching element and a first main terminal of a second of the two switching elements.

9. The converter as claimed in claim 1, wherein:
the submodule comprises a full-bridge with two half-bridges connected in parallel, having a first of the two half-bridges with a first and a second switching element connected in series and a second of the two half-bridges with a third and a fourth switching element connected in series;
the first submodule terminal is electrically connected to a node point of a second main terminal of the first switching element and to a first main terminal of the second switching element;
the second submodule terminal is electrically connected to a node point of a second main terminal of the third switching element and to a first main terminal of the fourth switching element; and
the first main terminals of the first and third switching element are electrically connected to one another via a further conductive layer on the cooling surface.

10. The converter as claimed in claim 9, wherein the further conductive layer is arranged between the conductive layers of the first and second submodule terminals on the cooling body.
